(19) United States
(12) Patent Application Publication
(10) Pub. No.: US 2002/0008311 A1
(43) Pub. Date: Jan. 24, 2002

(54) Semiconductor device and method of manufacturing the same

(76) Inventor: Naoto Kimura, Kumamoto (JP)

Correspondence Address: ROSENMAN & COLIN LLP, 575 MADISON AVENUE, NEW YORK, NY, 10022-2585, US

(21) Appl. No.: 09/900,331

(22) Filed: Jul. 6, 2001

(30) Foreign Application Priority Data
Jul. 17, 2000 (JP) 2000-215594

(51) Int. Cl. H01L 23/48

(52) U.S. Cl. 257/690; 257/701; 257/738

(57) ABSTRACT

A semiconductor device has a gap between a semiconductor chip mounted on a mounting plate and a glass epoxy substrate to be attached, and, at the time of resin sealing, molten resin is injected into the gap to form an adhesive layer. Thereby, the adhesive needed conventionally is not needed. In addition, by providing a metal mounting plate having excellent heat conductivity to the rear surface of the semiconductor chip, the high heat radiation effect can be obtained, thereby it can be applied to large-scale array.

### BACKGROUND OF THE INVENTION

1. Technical Field of the Invention

The present invention relates to a semiconductor device which has a CSP (Chip Size Package) structure and has a package body of a BGA (Ball Grid Array) structure and the method of manufacturing the same.

2. Description of the Related Art

Conventionally, this kind of semiconductor device has a CSP structure and has a package of BGA structure, in response to high integration of semiconductor functional element, pin multiplication and scale-up of a chip.

FIG. 1 is a cross-sectional view showing an example of the conventional semiconductor device. As shown in FIG. 1, for example, the semiconductor device of the CSP structure has a structure that a semiconductor chip 8 in which a semiconductor element is formed and a plurality of electrode pads 9 are formed on the surface thereof is mounted on a glass epoxy substrate 21 interposing an adhesive 22.

In addition, the electrode pads 9, 9a exposed on three rows of slits of the glass epoxy substrate 21 and a conductive pad 24 of a wiring 25 on the glass epoxy substrate 21 are connected to each other by a wire 7 which is a metal wire. A gap between the glass epoxy substrate 21 and the semiconductor chip 8 is filled with resin and a resin body 23 is formed so as to pile up the resin to envelop the wire 7. The electrode pads 9, 9a perform the same function, and are formed so as to transfer the signal of the semiconductor chip 8 to the outside. Also, the electrode pads 9, 9a are formed of, for example, aluminum alloy.

Further, a conductive pad 24 exposed on the glass epoxy substrate 21 is attached with a solder ball 10 for mounting to a wiring substrate.

However, in the above-mentioned conventional semiconductor device, an expensive adhesive 22 is used in adhering the semiconductor chip 8 to the glass epoxy substrate 21. Moreover, there is a problem that the process for adhering the semiconductor chip 8 and, therefore, the mounting process of the semiconductor chip 8 require long time and high cost.

Also, this kind of semiconductor device needs radiation of heat in case of large-scale array which generates high heat. However, in order to attach a radiator to the semiconductor chip after assembling, the number of the process becomes increased and, moreover, the expensive adhesive is required, thereby there is a problem that it can not be applied to the large-scale array which generates high heat.

### SUMMARY OF THE INVENTION

An object of the present invention is to provide a semiconductor device in which a semiconductor chip can be mounted on a substrate, without requiring the process for adhering the semiconductor chip to the substrate and without the expensive adhesive, and a radiator can be attached, if necessary, and the method of manufacturing the same.

A semiconductor device according to the present invention comprises a metal frame member in which a plate member is supported by a supporting member extending from an inner edge of the frame to the center thereof; a semiconductor chip in which a semiconductor element is formed and a plurality of electrode pads are formed on the surface thereof and which is mounted on said plate member; a substrate which is arranged apart from said surface of said semiconductor chip and in which conductive pads and wirings connected to said conductive pads are formed on the surface thereof and a plurality of slits exposing said electrode pad are formed; a metal wire of which one end is connected to said electrode pad and the other end is connected to the conductive pad of said substrate through the slit of said substrate; a resin member which is filled in a gap between said semiconductor chip and said substrate and rises from the slit of said substrate to envelop said metal wire; and a solder ball laid on the wiring of said substrate exposed from said resin member.

In addition, it is preferable that a gap between said substrate and said semiconductor chip is not more than 100 μm. Further, it is preferable that said resin member is thermosetting epoxy resin. On the other hand, it is preferable that said metal frame member is made of copper alloy. Preferably, said adhesive is a silver paste containing palladium.

In a method of manufacturing said semiconductor device according to the present invention, said frame member is obtained by cutting a band-shaped metal plate member having a plurality of frame member sections provided in a line into individual frame members, after adhering and mounting said semiconductor chips to the plate members of said frame member sections of said band-shaped metal plate member.

Also, in the manufacturing method, it is preferable that a band-shaped substrate member having a plurality of substrate sections provided in a line is arranged apart from said surface of said semiconductor chips provided on said band-shaped metal plate member. Said electrode pads of said semiconductor chips adhered to said plate members of said band-shaped metal plate member and said conductive pads of said substrate sections are connected each other by said metal wires. And said resin member is filled into the interval between said band-shaped metal plate member and said band-shaped substrate member. Also, said band-shaped metal plate member and said band-shaped substrate member are cut into individual semiconductor devices each of which contains individual frame member and individual substrate.

In the present invention, since the semiconductor device has a gap between a semiconductor chip and a substrate to be attached and molten resin is injected into the gap to form an adhesive layer at the time of resin sealing, the expensive adhesive needed conventionally is not needed. Moreover, the adhering process can be omitted, thereby the cost can be prominently reduced.

By providing a metal frame member having excellent heat conductivity to the rear surface of the semiconductor chip, the radiation effect of heat becomes high, thereby the present invention can be applied to large-scale array.

### BRIEF DESCRIPTION OF THE DRAWINGS

The above objects, other objects, features and advantages of the present invention will be better understood from the following description taken in conjunction with the accompanying drawings, in which:

FIG. 1 is a cross-sectional view showing a conventional semiconductor device.

FIG. 2A is a plan view showing a semiconductor device according to an embodiment of the present invention, FIG. 2B is a cross-sectional view taken by A-A line of FIG. 2A, and FIG. 2C is a partial perspective view excluding a resin body and a resin layer of FIG. 2A.

FIGS. 3A to 3C are schematic views for explaining a method of manufacturing the semiconductor device according to the embodiment of the present invention.

FIG. 4 is a cross-sectional view for explaining a resin sealing process in the method of manufacturing the semiconductor device according to the embodiment of the present invention.

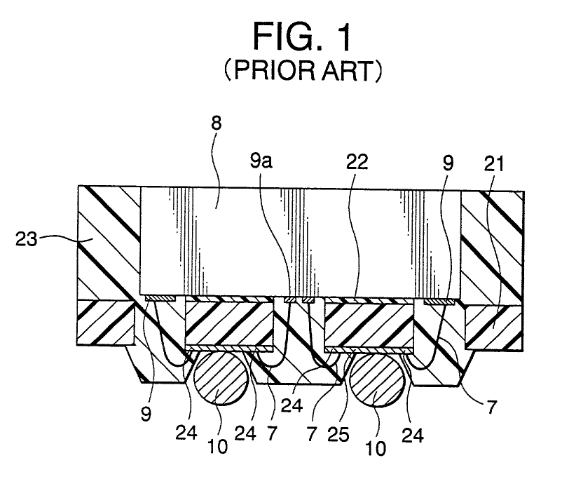

### THE PREFERRED EMBODIMENTS OF THE INVENTION

Hereinafter, the embodiments of the present invention will be explained with reference to the accompanying drawings.

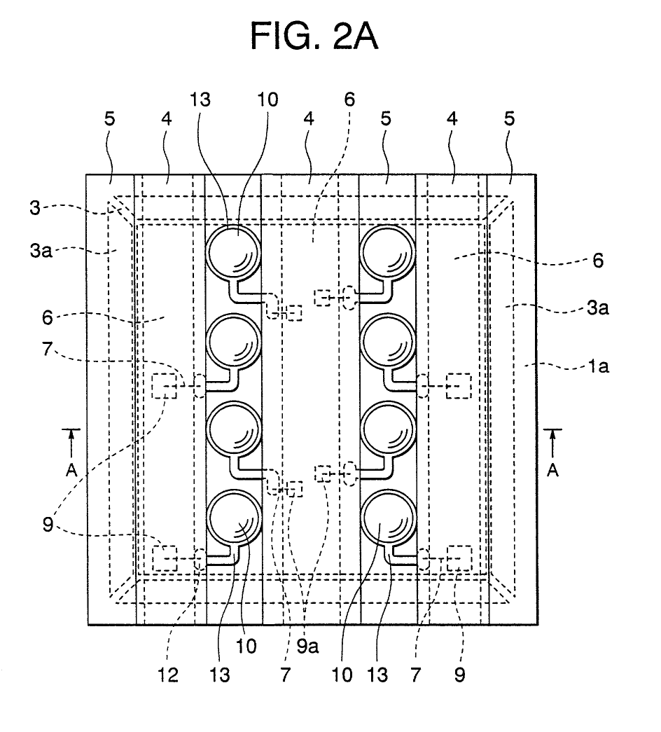

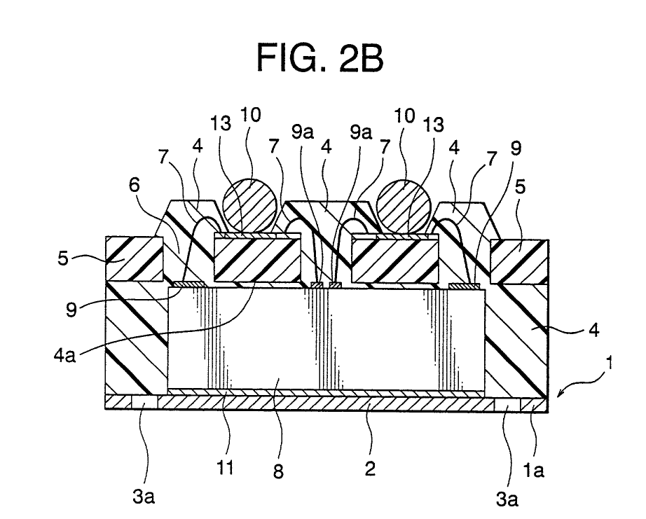

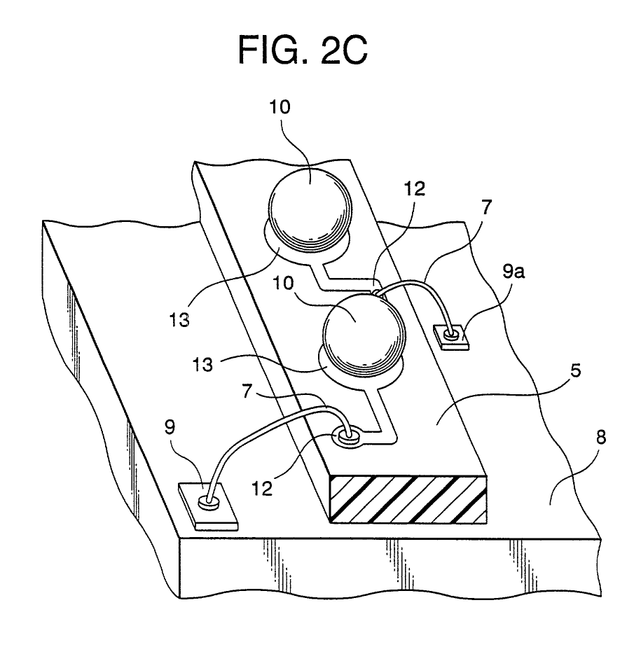

FIG. 2A is a plan view showing a semiconductor device according to an embodiment of the present invention, FIG. 2B is a cross-sectional view taken by A-A line of FIG. 2A, and FIG. 2C is a partial perspective view excluding a resin body and a resin layer of FIG. 2A. In this semiconductor device, as shown in FIGS. 2A to 2C, a frame member 1 is formed with cut-away portions 3a along four sides. A suspending pin 3 extending from four corners of inner side in an edge 1a to the center thereof is formed by the cut-away portions 3a, and a mounting plate 2 in the center portion is supported by the suspending pin 3. The frame member 1 is made of metal, and a semiconductor chip 8 is mounted on the mounting plate 2 by interposing a bonding metal 11 which is an adhesive. In the semiconductor chip 8, a semiconductor element is formed and electrode pads 9, 9a for transferring the signal of the semiconductor chip 8 to the outside are formed apart from each other in four rows on the surface thereof. A glass epoxy substrate 5 is mounted on the semiconductor chip 8 at a predetermined gap, and the glass epoxy substrate 5 is provided with a slit 6 in the position which is matched with the electrode pads 9, 9a. Also, a plurality of wirings 13 are formed on the top surface of the glass epoxy substrate 5 in the extending direction of the slit 6 at a predetermined interval. The wirings 13 are connected to electrode pads 12. The electrode pads 12 are formed to be alternately connected to the electrode pad 9 in an edge portion and the electrode pad 9a in a center portion with respect to the extending direction of the slit 6, and the electrode pads 9, 9a are connected to the electrode pad 12 by a wire 7. The gap and the space portion between the semiconductor chip 8 and the glass epoxy substrate 5 are filled and a resin body 4 and a resin layer 4a are formed so as to envelop the wire 7, except the area which the wirings 13 are formed such that the wirings 13 rise from the slit 6. A solder ball 10 is placed on a land portion in each wiring 13.

The point of the present embodiment different from the conventional example is to adhere the semiconductor chip 8 to the mounting plate 2 of the metal frame member 1 having excellent heat conductivity by a bonding metal 11 which is an adhesive. As mentioned later, the frame member 1 has no lead portion and is obtained by providing the cut-away portions 3a along the four sides in each areas of a plurality of areas and cutting a lead frame in which only the suspending pin 3 and mounting plate 2 connected to the suspending pin 3 are formed one by one every area. Also, it is preferable that the frame member 1 is made of copper alloy which has a better heat conduction than nickel-based alloy. Also, it is preferable that the bonding metal 11 is a silver paste including 20% of the palladium in order to improve migration.

In this manner, if the mounting plate 2 having excellent heat conductivity is attached to the rear surface of the semiconductor chip 8, though the semiconductor chip 8 generates the heat, the mounting plate 2 radiates the heat, thereby the temperature increment of the semiconductor chip 8 is suppressed. In addition, if necessary, a radiator may be attached to the mounting plate 2.

Further, another point of the present embodiment different from the conventional semiconductor device is that the expensive adhesive for adhering the glass epoxy substrate 5 to the semiconductor chip 8 is unnecessary. In other words, in the semiconductor device of the present embodiment, as mentioned later, the semiconductor chip 8 and glass epoxy substrate 5 are adhered to each other by the resin layer 4a formed by injecting the resin into the gap thereof at the time of resin sealing.

The resin layer 4a is composed of, for example, epoxy resin. If the thickness of the resin layer 4a is more than 100 μm, at the time of heat cycle test, crack is generated in the inner portion of the resin layer 4a because the thickness thereof is thick. Accordingly, it is preferable that the resin layer 4a is as thin as possible, but, if the gap between the semiconductor chip 8 and the glass epoxy substrate 5 is not more than 30 μm, there is a possibility that the epoxy resin is cured constantly before the epoxy is injected into the gap.

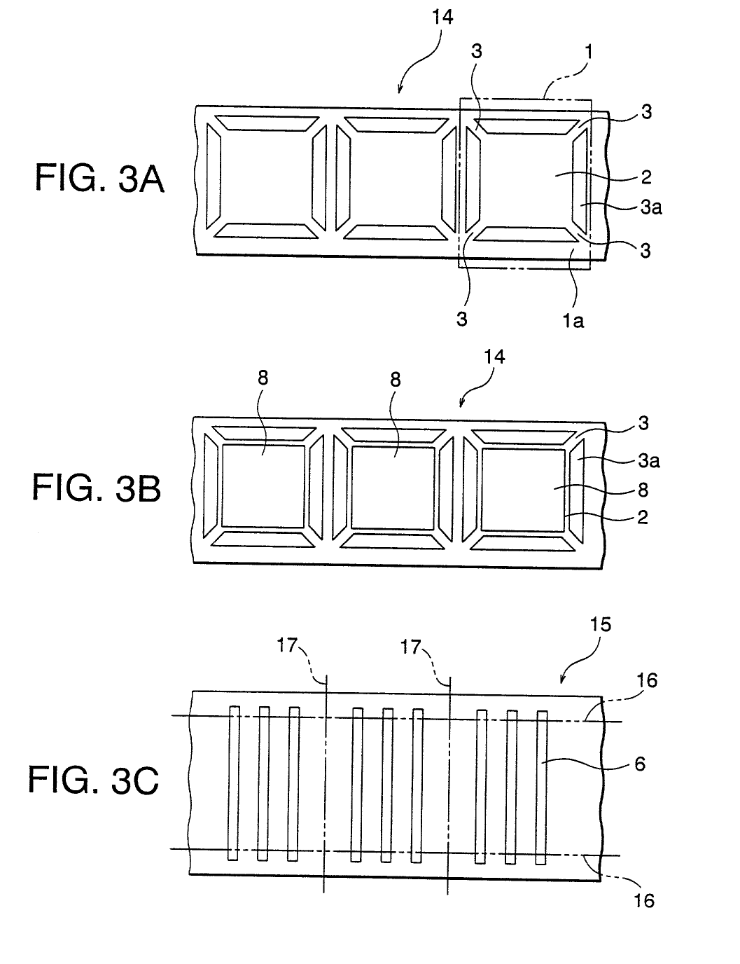

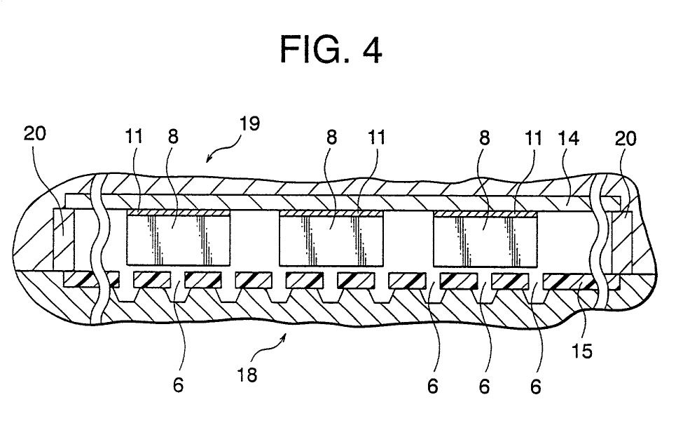

FIGS. 3A to 3C are schematic views for explaining a method of manufacturing the semiconductor device according to the embodiment of the present invention, and FIG. 4 is a cross-sectional view for explaining a resin sealing process in the method of manufacturing the semiconductor device according to the embodiment of the present invention. Next, the method of manufacturing the above-mentioned semiconductor device will be explained with reference to FIGS. 2A to 2C, FIGS. 3A to 3C, and FIG. 4.

First, as shown in FIG. 3A, the band-shaped metal plate member (lead frame) 14 which the plurality of frame members 1 shown in FIG. 2A are lined up in a direction and are integrated is prepared. In the band-shaped metal plate member 14, cut-away portions 3a opposite to long sides and short sides are formed in each areas to be the frame members 1, and a mounting plate 2 supported to the suspending pin 3 extended from four corners of the inner side in the frame member 1a to the center thereof is formed by the cut-away portions 3a. Also, since the band-shaped metal plate member (lead frame) 14 has no lead having fine pitch like as prior art and only the suspending pin 3 is formed by forming the cut-away portions 3a, the band-shaped metal plate member can be easily manufactured by a press working.

Next, the band-shaped metal plate member 14 is mounted on a stage of a die mount (not shown). And, a paste containing silver and palladium is applied to the mounting plate 2, and, as shown in FIG. 3B, the semiconductor chip 8 is picked up by a collet (not shown) to be mounted on the mounting plate 2, and then the mounting plate 2 and the semiconductor chip 8 are adhered to each other by heating.

Next, as shown in FIG. 3C, the band-shaped substrate member 15 is prepared. The band-shaped substrate member 15 is formed by forming printed wiring to the glass epoxy resin plate and forming the slit 6 in the position which is matched with the electrode pads 9, 9a of the semiconductor chip 8. In other words, the plurality of glass epoxy substrates 5 shown in FIG. 2A are lined up in a direction and are integrated. Moreover, the slit 6 in FIG. 2A is previously formed by the press working such that separate substrates are not scattered and the length thereof is shorter than the width of the band-shaped substrate member 15.

Next, the band-shaped metal plate member 14 in FIG. 3B is opposite to the band-shaped substrate member 15 in FIG. 3C, both ends thereof are fixed to each other by a temporary fixing member 20, and, as shown in FIG. 2B, these are assembled such that the gap between the semiconductor chip 8 and the glass epoxy substrate 5 becomes not more than 100 μm. And, as occasion demands, a core is inserted so as not to deform by a bonding tool. And, the assembly is mounted on a stage of a wire bonding unit (not shown) and, as shown in FIGS. 2A and 2B, the electrode pads 9, 9a and the conductive pad 12 are connected to each other by a wire 7.

Next, as shown in FIG. 4, the band-shaped metal plate member 14 and the band-shaped substrate member 15 of which both ends are assembled by the temporary fixing member 20 are inserted into a cavity formed by an upper mold 19 and a lower mold 18. And, the molten resin injected into the cavity is inserted into the space between the adjacent semiconductor chips 8, the gap between the semiconductor chip 8 and the substrate, and the slit 6, so that as shown in FIG. 2B, the resin layer 4a and the resin body 4 are formed.

Next, a resin sealing body taken out from the upper mold 19 and the lower mold 18 is set to a slicing unit, and is divided to separate semiconductor devices by contacting a cutter along to cut lines 16 and 17 shown in FIG. 3C. And, by a solder ball mounting jig, as shown in FIG. 2B, the solder ball 10 is mounted on each wiring 13, and the assembling of the semiconductor is completed.

Like this, conventionally, the semiconductor device was assembled one by one for every chip, but, in the present embodiment, by dividing to separate semiconductor devices after assembling the band-shaped substrate plate member 15 and the band-shaped metal plate member 14 mounting the plurality of semiconductor chips 8, the assembly time of one semiconductor device can be considerably reduced. In addition, in the present embodiment, in order to explain the present invention easily, the semiconductor chip 8 was assembled in a state of lining up in a single line, but it is possible to assemble in plural lines.

What is claimed is:

1. A semiconductor device comprising:
a metal frame member in which a plate member is supported by a supporting member extending from an inner edge of the frame to the center thereof;
a semiconductor chip in which a semiconductor element is formed and a plurality of electrode pads are formed on the surface thereof and which is mounted on said plate member by an adhesive;
a substrate which is arranged apart from said surface of said semiconductor chip and in which conductive pads and wirings connected to said conductive pads are formed on the surface thereof and a plurality of slits exposing said electrode pad are formed;
a metal wire of which one end is connected to said electrode pad and the other end is connected to the conductive pad of said substrate through the slit of said substrate;
a resin member which is filled in a gap between said semiconductor chip and said substrate and rises from the slit of said substrate to envelop said metal wire; and
a solder ball laid on the wiring of said substrate exposed from said resin member.

2. The semiconductor device according to claim 1, wherein a gap between said substrate and said semiconductor chip is not more than 100 μm.

3. The semiconductor device according to claim 1, wherein said resin member is thermosetting epoxy resin.

4. The semiconductor device according to claim 2, wherein said resin member is thermosetting epoxy resin.

5. The semiconductor device according to claim 1, wherein said metal frame member is made of copper alloy.

6. The semiconductor device according to claim 2, wherein said metal frame member is made of copper alloy.

7. The semiconductor device according to claim 3, wherein said metal frame member is made of copper alloy.

8. The semiconductor device according to claim 4, wherein said metal frame member is made of copper alloy.

9. The semiconductor device according to claim 1, wherein said adhesive is a silver paste containing palladium.

10. A method of manufacturing a semiconductor device, said semiconductor device comprising: a metal frame member in which a plate member is supported by a supporting member extending from an inner edge of the frame to the center thereof; a semiconductor chip in which a semiconductor element is formed and a plurality of electrode pads are formed on the surface thereof and which is mounted on said plate member by an adhesive; a substrate which is arranged apart from said surface of said semiconductor chip and in which conductive pads and wirings connected to said conductive pads are formed on the surface thereof and a plurality of slits exposing said electrode pad are formed; a metal wire of which one end is connected to said electrode pad and the other end is connected to the conductive pad of said substrate through the slit of said substrate; a resin member which is filled in a gap between said semiconductor chip and said substrate and rises from the slit of said substrate to envelop said metal wire; and a solder ball laid on the wiring of said substrate exposed from said resin member,
in which said frame member is obtained by cutting a band-shaped metal plate member having a plurality of frame member sections provided in a line into individual frame members, after adhering and mounting said semiconductor chips to the plate members of said frame member sections of said band-shaped metal plate member.

11. The method of manufacturing a semiconductor device according to claim 10, wherein a band-shaped substrate member having a plurality of substrate sections provided in a line is arranged apart from said surface of said semiconductor chips provided on said band-shaped metal plate member; said electrode pads of said semiconductor chips adhered to said plate members of said band-shaped metal plate member and said conductive pads of said substrate sections are connected each other by said metal wires; said resin member is filled into the interval between said band-shaped metal plate member and said band-shaped substrate member; and said band-shaped metal plate member and said band-shaped substrate member are cut into individual semiconductor devices each of which contains individual frame member and individual substrate.
